(19) United States
(12) Patent Application Publication
(10) Pub. No.: US 2012/0207426 A1
(43) Pub. Date: Aug. 16, 2012

(54) FLIP-CHIP PACKAGING FOR DENSE HYBRID INTEGRATION OF ELECTRICAL AND PHOTONIC INTEGRATED CIRCUITS

(75) Inventors: FUAD E. DOANY, KATONAH, NY (US); BENJAMIN G. LEE, NEW YORK, NY (US); CLINT L. SCHOW, OSSINING, NY (US)

(73) Assignee: INTERNATIONAL BUSINESS MACHINES CORPORATION, ARMONK, NY (US)

(21) Appl. No.: 13/028,814

(22) Filed: Feb. 16, 2011

(51) Int. Cl. G02B 6/12; H01L 33/48

(52) U.S. Cl. 385/14; 438/25; 257/E33.056

(57) ABSTRACT

A chip system and method includes a photonics chip and an electrical integrated circuit (IC) flip-chip coupled to the photonics chip to form an optochip. The IC or the photonics chip includes an array of bond pads for attachment to the other. The optochip has an array of bond pads for subsequent attachment to a carrier where the photonics chip includes an exposed edge to connect with at least one waveguide.

### GOVERNMENT RIGHTS

This invention was made with Government support under Contract No. HR0011-08-C-0102 awarded by the Defense Advanced Research Projects Agency (DARPA). The Government has certain rights in this invention.

### BACKGROUND

1. Technical Field

The present invention relates to chip packaging and more particularly to hybrid integration configurations for electrical and photonic chips.

2. Description of the Related Art

Flip-chip technology includes methods for interconnecting semiconductor devices, such as integrated circuit (IC) chips to external circuitry using solder bumps that have been deposited onto chip pads. The solder bumps are deposited on the chip pads on a top side of a wafer to mount the chip to external circuitry (e.g., a circuit board or another chip or wafer). The wafer is flipped over so that its top side faces down, and aligned so that its pads align with matching pads on the external circuit, and then the solder is flowed to complete the interconnect. This technique is in contrast to wire bonding, in which the chip is mounted upright, and wires are used to interconnect the chip pads to external circuitry.

Commercial optical transceiver (TRX), transmitter (TX) and receiver (RX) implementations that utilize integrated photonics chips (e.g., Si photonics or InP) are limited to low-density wire bond packaging. This packaging approach is severely limited in terms of its ability to scale to high numbers of channels (e.g., greater than 10 channels) and high channel data rates.

### SUMMARY

A chip system and method includes a photonics chip and an electrical integrated circuit (IC) flip-chip coupled to the photonics chip to form an optochip. The IC or the photonics chip includes an array of bond pads for attachment to the other. The optochip has an array of bond pads for subsequent attachment to a carrier where the photonics chip includes an exposed edge to connect with at least one waveguide.

Another chip system includes a carrier chip having a recess formed therein and having carrier bond pads, a photonics chip having an exposed edge to connect with at least one waveguide and an electrical integrated circuit (IC) flip-chip coupled to the photonics chip to form an optochip by employing a first array of bond pads formed on one of the IC and the photonics chip for attachment to the other of the IC and the photonics chip. The optochip includes a second array of bond pads for subsequent attachment to the carrier bond pads by flip-chip coupling such that a portion of the optochip fits within the recess of the carrier.

A method for fabricating an optical signaling device includes flip-chip bonding a photonics chip and an electrical integrated circuit (IC) using a first solder to form an optochip; flip-chip bonding the optochip to a carrier using a second solder having a melting point less than that of the first solder and connecting at least one waveguide to an exposed edge of the photonics chip.

These and other features and advantages will become apparent from the following detailed description of illustrative embodiments thereof, which is to be read in connection with the accompanying drawings.

### BRIEF DESCRIPTION OF DRAWINGS

The disclosure will provide details in the following description of preferred embodiments with reference to the following figures wherein:

FIG. 1A is a side view of an optical device assembled using flip-chip bonding in accordance with the present principles;

FIG. 1B is a top view of an optical device assembled using flip-chip bonding in accordance with the present principles;

FIG. 2 is a side view of an optical device assembled using flip-chip bonding and includes a heat sink and an additional module formed in a carrier recess in accordance with the present principles;

FIGS. 3A-3D are views showing a plurality of exposed edge configurations for connecting waveguides to a photonics chip in accordance with the present principles;

FIG. 4 is a side view of an optical device assembled using flip-chip bonding and includes a photonics chip sized to fit in a joint between an IC and a carrier in accordance with the present principles;

FIG. 5 is a side view and an inset view of an optical device assembled with non-horizontal fibers attached to the photonics chip in accordance with the present principles;

FIG. 6 is a side view of an optical device assembled using flip-chip bonding where an IC is disposed in a recess of a carrier instead of a photonics chip in accordance with the present principles;

FIG. 7 is a top view of an illustrative optical device having multiple optochips and conventional chips on a same carrier in accordance with the present principles;

FIG. 8A is a side view of an optical device having through vias formed through an IC to make a direct connection between a carrier and a photonics chip in accordance with the present principles;

FIG. 8B is a side view of an optical device having through vias formed through a photonics chip to make a direct connection between a carrier and an IC in accordance with the present principles; and

FIG. 9 is a block/flow diagram showing an illustrative method for fabricating an optical device in accordance with the present principles.

### DETAILED DESCRIPTION OF PREFERRED EMBODIMENTS

In accordance with the present principles, highly-integrated hybrid packaging is employed that exclusively utilizes flip-chip bonding to construct dense, low-power and high-speed transmitter (TX), receiver (RX), and/or transceiver (TRX) modules. In useful embodiments, hybrid integration of two components includes a photonic optical chip and an electrical integrated circuit (IC). A resulting component is an optochip, which is a component with high-speed optical functionality that is further flip-chip packaged to an organic or ceramic carrier. One preferred substrate material for the photonic chip is Si.

Photonic circuits offer extremely high-density integration (nm-scale), complementary metal oxide semiconductor (CMOS) and SiGe bipolar process compatibility, and low fabrication cost. Optical devices (e.g., modulators and detectors) have been demonstrated to operate at speeds up to 40 Gb/s and beyond. In addition, wavelength division multiplexing (WDM) can be straightforwardly incorporated into the Si photonic circuits, offering off-chip optical coupling of 10× to 100× more channels per fiber compared to parallel implementations. This feature takes full advantage of the integration capability of the Si photonic structures. Because of their sub-micron dimensions, tens to hundreds of thousands of devices can be incorporated in a square centimeter. Furthermore, optical input/output (I/O) of tens of Tb/s can be achieved off a single edge of a centimeter-scale chip into a linear array of optical fibers (e.g., ˜100 fibers).

A preferred technology for the electronic amplifier chip or other electrical chip is also silicon. Both CMOS and bipolar Si technologies provide high-density, low-power, and low-cost amplifier circuits that can drive optical circuits. Flip-chip assembly of the electronic and photonic chips provides optimal integration including high-speed and low power operation enabled through minimizing parasitic effects while high density and low manufacturing cost are enabled by the capabilities of Si manufacturing. The hybrid approach permits both components, the photonics chip and the electrical IC, to be separately optimized for performance and yield. The components are then co-packaged.

The flip-chip assembly of optochips to a high-density chip carrier maintains the high performance of a complete integrated package. Multiple photonic/electronic optochips can be integrated into a multi-chip carrier providing extremely high-bandwidth (e.g., 0.1-10 Tb/s) and dense optical I/O. These and other advantages of the flip-chip packaging are not obtainable with conventional wire bonding technology that is currently used by the transceiver industry.

Aspects of the present invention are described below with reference to flowchart illustrations and/or block diagrams of methods, apparatus and systems according to embodiments of the invention. It will be understood that each block of the flowchart illustrations and/or block diagrams, and combinations of blocks in the flowchart illustrations and/or block diagrams, produce an article of manufacture. The flowchart and block diagrams in the Figures illustrate the architecture, functionality, and operation of possible implementations of systems and methods according to various embodiments of the present invention. In this regard, each block in the flowchart or block diagrams may represent a module or hardware for implementing the specified function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

It is to be understood that the present invention will be described in terms of a given illustrative architecture using particular wafer materials and technologies; however, other architectures, structures, substrate materials and process features and steps may be varied within the scope of the present invention.

The circuits as described herein may be part of a design for an integrated circuit chip or mulitchip package. The chip designs may be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer may transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

The methods as described herein may be used in the fabrication of integrated circuit chips or chip packages. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

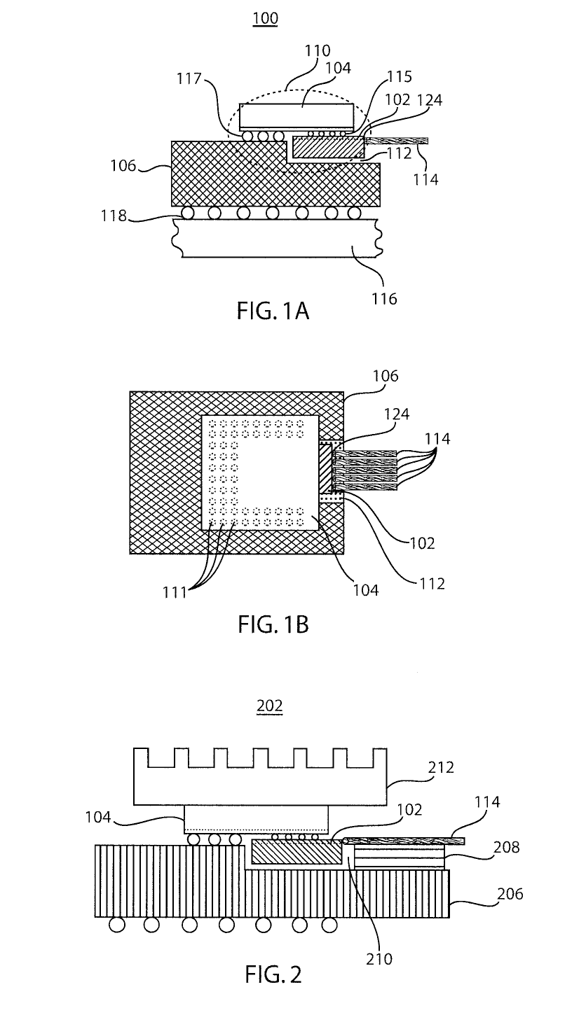

Referring now to the drawings in which like numerals represent the same or similar elements and initially to FIGS. 1A and 1B, a packaging platform 100 for producing low-cost, low profile and small-footprint parallel optical transmitters, receivers, or transceivers based on photonic integrated circuits is illustratively depicted in accordance with one embodiment. FIG. 1A shows a side view of the platform 100 while FIG. 1B shows a top view. The platform 100 (and other platforms shown and described herein) may include optical transceivers (TRX), transmitters (TX) and/or receivers (RX) which employ a flip-chip coupling/packaging to scale the devices to high numbers of channels (e.g., 100's of channels and beyond) and high channel data rates (e.g., 20-40 Gb/s and beyond).

Platform 100 includes a photonic chip 102, which may be fabricated in silicon or other semiconductor material. The present approach is applicable to other optical component technologies such as: InP; GaAs photonic integrated circuits; other III-V or II-VI semiconductors used to construct optical devices; polymer-based photonic devices; etc. An electrical integrated circuit (IC) 104 is coupled to the photonic chip 102 preferably using a flip-chip packaging process. The electrical IC 104 may include an amplifier or other device or devices that support the optical functions of the device. The electrical IC 104 carrying the photonics chip 102 is then coupled to a chip carrier 106 using a flip-chip packaging process. The combined electrical IC 104 and the photonics chip 102 may be collectively referred to as an optochip 110.

The chip carrier 106 may include an organic (or ceramic) substrate material. The chip carrier 106 includes a recess 112 formed in the substrate thereof to accommodate the photonics chip 102 and to present an edge of the photonic chip to permit the attachment of optical fibers 114 to the photonics chip 102.

The use of the flip-chip packaging process to connect both the photonics chip 102 to the electrical amplifier IC 104, and the optochip 110 to the carrier chip 106 minimizes both the footprint of the platform 100 (e.g., assembled module) as well as the parasitic inductance and capacitance incurred in the connections between chips. This permits the production of modules with many parallel channels, and also maximizes the speed that can be obtained for each individual channel.

In the present implementation, the IC 104 and photonics chip 102 are first flip-chip soldered together using a relatively high-melting temperature solder 115, e.g., lead-free or AuSn. Subsequent flip-chip bonding of the optochip 110 to the carrier chip 106 is carried out using a lower melting point solder 117, e.g., lead-free or tin-lead. A final attachment of the carrier 106 to a system board 116 can be carried out either through a connector (e.g., land grid array) or directly soldered using an even lower melting point solder 118. An illustrative solder hierarchy includes AuSn solder for the optochip 110 assembly, Pb-free solder for the optochip-to-carrier bonding, and eutectic Pb—Sn solder for the final system-board attachment. Other solder materials that support a similar hierarchy can also be employed.

The IC 104 may be fabricated using standard fabrication processes. Although CMOS is a preferred technology, SiGe bipolar, InP, GaAs GaN or other technologies may also be employed to construct the IC 104. The IC 104 may include an amplifier for a transmitter, receiver or transceiver, for example. An area on the IC 104 is reserved for the flip-chip soldering of the photonics chip 102 directly to the electrical IC 104. Transmitter (e.g., a modulator driver) and photodiode receiver circuits are designed with input/output pads near the location of the photonic chip attachment. Surrounding the photonic chip site at the periphery of the optochip 110 are pads 111 for input/output data signals to/from the IC 104 along with power, ground, and control connections. These peripheral pads 111 are provided for soldering the assembled optochip 110 to the carrier chip 106 and may be, e.g., about 100 microns on a 200 micron pitch, 75 microns on a 150 micron pitch, etc. The pad diameter and pitch can be further reduced with advances in carrier technology. The photonics chip 102 may include active and/or passive optical devices, including but not limited to lasers, optical modulators, photodetectors, waveguides, wave division multiplexing (WDM) multiplexers and demultiplexers, power splitters, input/output couplers, mode converters, switches, detectors, spot-size converters, grating couplers, etc. In the embodiment shown, one edge 124 of the photonics chip 102 is used for optical I/O through a linear array of waveguides (e.g., fibers) that extend to and are terminated at the edge 124 of the substrate. This configuration facilitates coupling to linear arrays of fibers 114, as shown in the fully packaged transceiver module of FIG. 2.

Referring to FIG. 2, another platform 202 for a complete hybrid transceiver package includes a larger recess 210 to accept the photonics chip 102 and an additional module 208. The additional module 208 may include a fiber array module with attached optical fibers 114 prefixed to the module 208. The module 208 can attach to or sit directly on a carrier chip 206. A heat sink or spreader 212 may be included and attached to the IC 104 and/or other parts of the optochip 110.

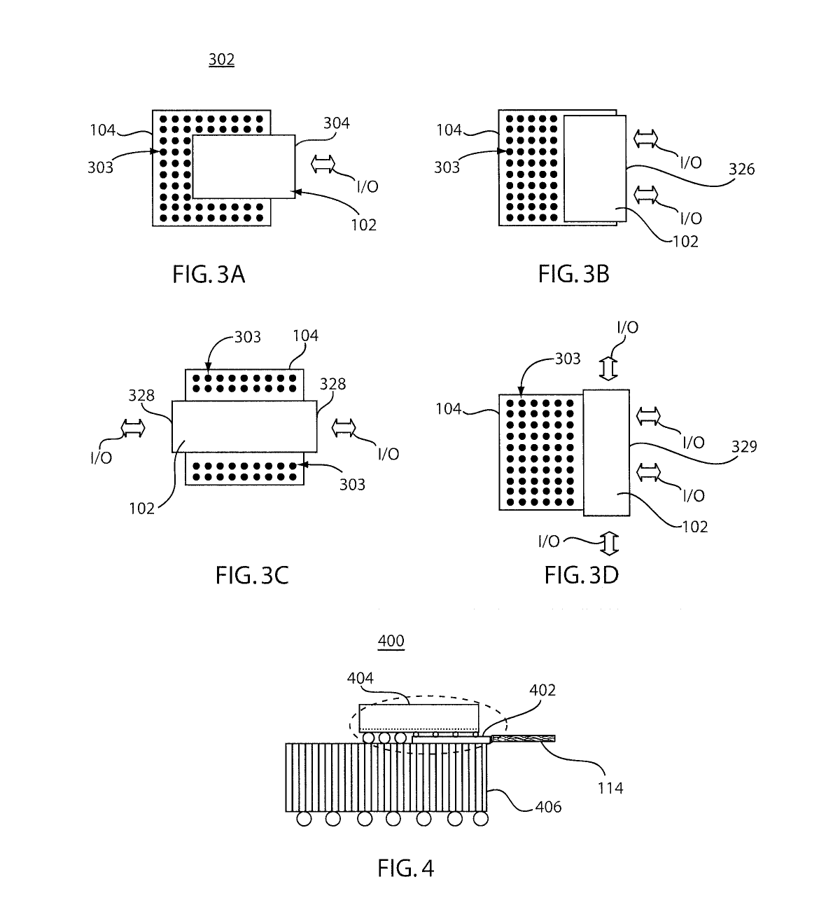

Referring to FIGS. 3A-3D, alternate implementations of the hybrid optochip 110 with different optical and electrical I/O configurations are illustratively shown. In FIG. 3A, a platform 302 is similar to that of platform 100 and includes IC 104 with IC bond pads 303 on three sides of the photonics chip 102. Optical inputs/outputs (I/O) may be connected along edge 304. In FIG. 3B, bond pads 303 are placed on one side of the photonics chip 102. The photonics chip 102 includes a longer exposed edge 326 and enables a greater number of optical I/Os.

In FIG. 3C, IC bond pads 303 are on two sides of the photonics chip 102. The photonics chip 102 extends over the IC 104 to permit access to two edges 328 for optical I/Os. In FIG. 3D, bond pads 303 are placed on one side of the photonics chip 102. The photonics chip 102 includes a longer exposed edge 329 on three sides and enables a greater number of optical I/Os.

Referring to FIG. 4, a platform 400 includes a photonics chip 402 that is thinned or reduced in thickness so as to fit between an IC 404 and a carrier 406. In other embodiments, a recess (112, 210) is fabricated in the carrier 106, 206 to accommodate the photonics chip 102. The photonics chip 402 can be thinned to, e.g., about 50 microns or less such that the thickness is less than an optochip-to-carrier solder height. In this way, the thinned photonics chip 402 avoids the need for a fabricated recess in the carrier 406.

Referring to FIG. 5, a package platform 500 is shown which utilizes angled, preferably, near-normal optical coupling. The photonics chip 102 includes a portion 501 which extends beyond the IC 104. The portion 501 permits the connection of optical fibers 114 at an angle (e.g., between a few degrees to about 90 ninety degrees). The optical I/O from a transceiver is therefore changed from being co-planar to the photonics chip (102), i.e., the optical fibers are no longer arranged horizontally and aligned to a planar array of waveguides and are instead in a non-horizontal arrangement. Utilizing near-vertical grating-based optical couplers (not shown), the optical I/O is directed at an angle, e.g., near-normal to the plane of the photonics chip 102. The near-normal approach utilizes a fiber array introduced at a near-90 degree angle. An inset 510 shows a three-dimensional view of a coupling to a linear fiber array 512. Although a linear fiber array 512 is illustratively presented, the near-normal coupling supports 2-D arrays of large numbers of fibers on, e.g., ˜100-250 microns pitch.

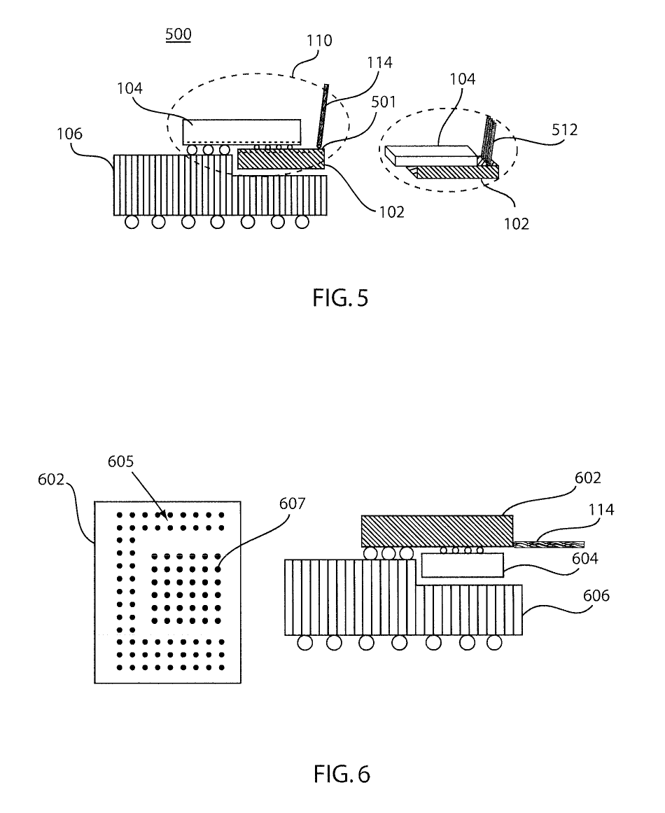

Referring to FIG. 6, in another embodiment, a photonics-to-carrier bonding is performed with an IC 604 first bonded to a photonics chip 602 before connecting the photonics chip 602 to the carrier 606. Instead of the electrical IC 604 being directly bonded to the carrier 606, the photonics chip 602 has bond pads 605 for attachment to the carrier 606 and separate bond pads 607 for attachment to the IC 604. The photonics chip 602 can be constructed to have different arrangements for bond pads 605 for attachment to the carrier 606 and for bond pads 607 for attachment to the IC 604 other than that which is illustratively shown. In the configuration shown, electrical I/O, power, ground and control signals are routed through wiring in the photonics chip 602 for connection between the carrier 606 and the IC 604.

The illustrative embodiments shown and described above include a single hybrid optochip attached to the chip carrier. However, all embodiments are readily extendable to include multiple optochips on a single chip carrier. Furthermore, this same multi-chip carrier may include multiple electronic chips, e.g., processors, memory, application specific ICs (ASICs), switches/routers, field programmable gate arrays (FPGAs), etc.

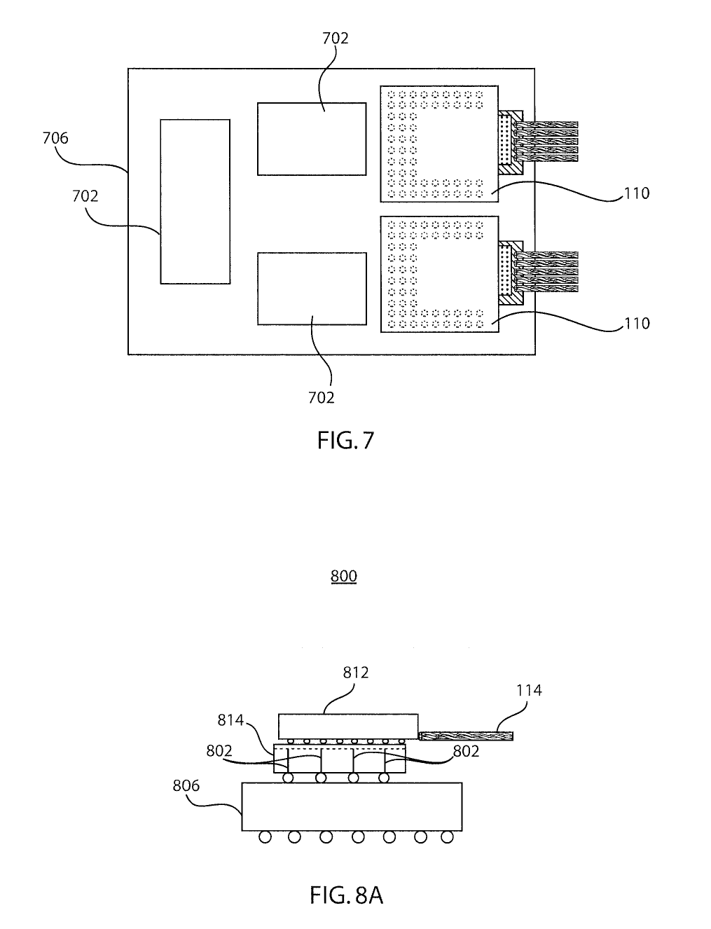

Referring to FIG. 7, an illustrative multi-chip module 700 is shown incorporating hybrid optochips 110 and other devices (e.g., ICs) 702. The optochips 110 and devices 702 are preferably integrated into a single carrier 706. Devices 702 may include electronic chips, e.g., processors, memory, application specific ICs (ASICs), switches/routers, field programmable gate arrays (FPGAs), etc.

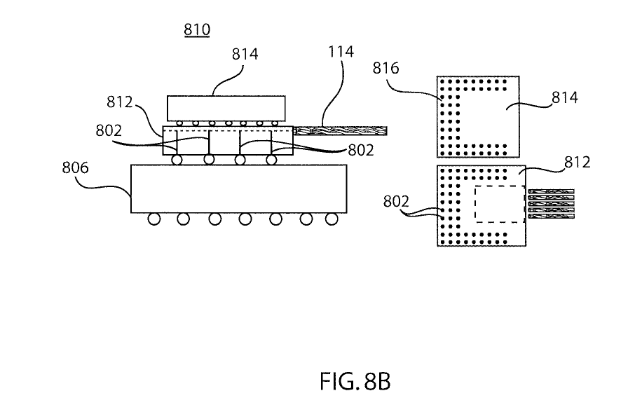

Referring to FIGS. 8A and 8B, a 3-D package 800 includes electrical through vias 802 through an electrical IC 814 (FIG. 8A). The through vias 802 connect the carrier 806 to a photonic chip 812. In another embodiment (FIG. 8B), a 3-D package 810 includes electrical through vias 802 through a photonics chip 812. The through vias 802 connect the carrier 806 to an IC 814. Bond pads 816 on IC 814 correspond with and connect to vias 802 on photonics chip 812 (or vice versa for the embodiment of FIG. 8A). Electrical ICs and/or photonics chips can be fabricated with through-silicon electrical vias 802. Additional 3-D packaging embodiments are also possible, for example, through vias 802 may be employed with any of the other embodiments described herein, e.g., FIGS. 1A, 2, 4, 5, etc.

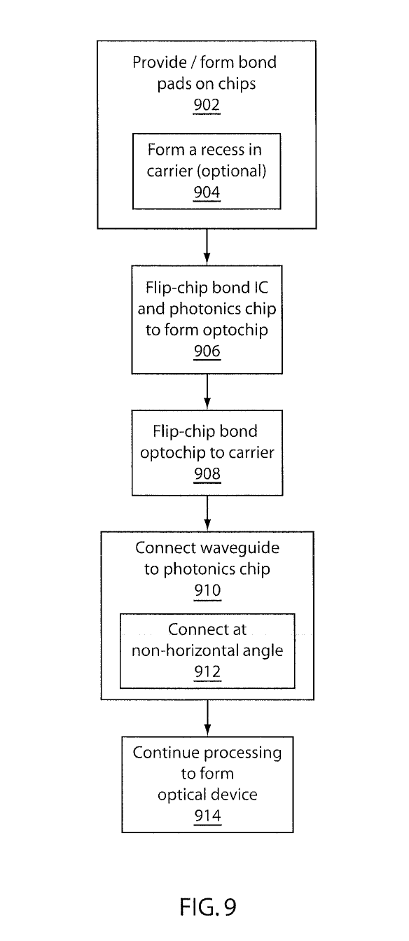

Referring to FIG. 9, a method for fabricating an optical signaling device (e.g., RX, TX, TRX, etc.) is illustratively shown. In block 902, bonding pads are provided on a photonics chip, an electrical integrated circuit (IC), a carrier and any other chips that will be included in the assembly. In block 904, a recess may be formed in the carrier which is sized to fit at least one of the IC and the photonics chip. The recess may be sized to fit other chips as well, e.g., a waveguide array module, etc.

In block 906, a photonics chip and an electrical integrated circuit (IC) are flip-chip bonded to each other using a first solder to form an optochip. The manner in which these devices are bonded may take a plurality of different forms. For example, the photonics chip may be flip-chip bonded to the IC or vice versa, a thinned photonics chip may be bonded to the IC, etc. In block 908, the optochip is flip-chip bonded to a carrier using a second solder having a melting point less than that of the first solder. It is preferable that the photonics chip of the optochip have at least one exposed side to permit access thereto for optical waveguide connections. In block 910, at least one waveguide is connected to the exposed edge of the photonics chip. In block 912, connecting at least one waveguide may be at a non-horizontal angle on the photonics chip. In block 914, processing continues to complete the optical signaling device.

Having described preferred embodiments for flip-chip packaging for dense hybrid integration of electrical and photonic integrated circuits (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

What is claimed is:

1. A chip system, comprising:
a photonics chip;
an electrical integrated circuit (IC) flip-chip coupled to the photonics chip to form an optochip, wherein one of the IC and the photonics chip includes an array of bond pads for attachment to the other of the IC and the photonics chip and the optochip having an array of bond pads for subsequent attachment to a carrier where the photonics chip includes an exposed edge to connect with at least one waveguide.

2. The system as recited in claim 1, wherein the exposed edge extends beyond the IC chip to facilitate optical coupling.

3. The system as recited in claim 1, wherein the carrier includes a recess in a top surface configured to receive the photonics chip.

4. The system as recited in claim 3, wherein the recess is configured to permit more than one chip therein.

5. The system as recited in claim 3, wherein the recess permits exposure of a plurality of edges of the photonics chip to permit access for optical inputs and outputs.

6. The system as recited in claim 1, wherein the photonics chip has a thickness to enable the photonics chip to fit between a joint between the IC and the carrier.

7. The system as recited in claim 1, wherein the carrier includes a recess in a top surface configured to receive the IC.

8. The system as recited in claim 1, wherein the carrier includes a multichip carrier including two or more chips or chip assemblies.

9. The system as recited in claim 1, further comprising a heat sink coupled to the optochip.

10. The system as recited in claim 1, wherein one of the IC and the photonics chip includes through vias that pass through the IC or the photonics chip to make a direct connection with the carrier.

11. The system as recited in claim 1, wherein the photonics chip has an exposed portion to permit an angled connection of a light guide.

12. The system as recited in claim 1, wherein the system includes at least one of an optical receiver, an optical transmitter and an optical transceiver.

13. A chip system, comprising:
a carrier chip having a recess formed therein and having carrier bond pads;
a photonics chip having an exposed edge to connect with at least one waveguide;
an electrical integrated circuit (IC) flip-chip coupled to the photonics chip to form an optochip by employing a first array of bond pads formed on one of the IC and the photonics chip for attachment to the other of the IC and the photonics chip, the optochip including a second array of bond pads for subsequent attachment to the carrier bond pads by flip-chip coupling such that a portion of the optochip fits within the recess of the carrier.

14. The system as recited in claim 13, wherein the exposed edge extends beyond the IC chip to facilitate optical coupling.

15. The system as recited in claim 13, wherein the recess is configured to permit more than one chip therein.

16. The system as recited in claim 13, wherein the recess permits exposure of a plurality of edges of the photonics chip to permit access for optical inputs and outputs.

17. The system as recited in claim 13, wherein the recess is configured to receive one of the IC and the photonics chip.

18. The system as recited in claim 13, wherein the carrier includes a multichip carrier including two or more chips or chip assemblies.

19. The system as recited in claim 13, further comprising a heat sink coupled to the optochip.

20. The system as recited in claim 13, wherein one of the IC and the photonics chip includes through vias that pass through the IC or the photonics chip to make a direct connection with the carrier.

21. The system as recited in claim 13, wherein the photonics chip has an exposed portion to permit an angled connection of a light guide.

22. The system as recited in claim 13, wherein the system includes at least one of an optical receiver, an optical transmitter and an optical transceiver.

23. A method for fabricating an optical signaling device, comprising:
flip-chip bonding a photonics chip and an electrical integrated circuit (IC) using a first solder to form an optochip;
flip-chip bonding the optochip to a carrier using a second solder having a melting point less than that of the first solder; and
connecting at least one waveguide to an exposed edge of the photonics chip.

24. The method as recited in claim 23, further comprising forming a recess in the carrier configured to fit at least one of the IC and the photonics chip.

25. The method as recited in claim 23, wherein connecting includes connecting at least one waveguide at a non-horizontal angle on the photonics chip.
